(19) United States
(12) Patent Application Publication
(10) Pub. No.: US 2024/0170262 A1
(43) Pub. Date: May 23, 2024

(54) SYMMETRIC SEMICONDUCTOR PROCESSING CHAMBER

(71) Applicant: Applied Materials, Inc., Santa Clara, CA (US)

(72) Inventor: Yogananda SARODE, Bangalore (IN)

(21) Appl. No.: 18/429,110

(22) Filed: Jan. 31, 2024

Related U.S. Application Data
(62) Division of application No. 17/374,808, filed on Jul. 13, 2021.

(51) Int. Cl. H01J 37/32

(52) U.S. Cl. CPC H01J 37/32449; H01J 37/32183; H01J 37/32733; H01J 37/32834; H01J 37/32899; H01J 2237/334

(57) ABSTRACT

A processing chamber and a processing platform having the same are provided. In one example, the processing chamber includes a process module enclosing a process region, a flow module, a chassis, and a substrate support assembly. The flow module includes four pairs of radial walls connecting outer walls and inner walls of the flow module. The outer, inner and radial walls define four evacuation channels and a center portion. The center portion and evacuation channels fluidly are isolated from each other. The flow module includes four through holes formed 90 degrees apart through the outer wall that are fluidly coupled to the center portion. The chassis is sealingly coupled to the inner wall of the flow module. The substrate support assembly is disposed in the process region to support a substrate therein, wherein an interior of the substrate support assembly is accessible through the four through holes.

### CROSS REFERENCE TO RELATED APPLICATION

This Application is a divisional of U.S. Non-Provisional application Ser. No. 17/374,808, filed on Jul. 13, 2021 of which is incorporated herein by reference in its entirety.

### BACKGROUND

### Field

Examples of the present disclosure generally relate to a processing chamber that provides thermal, electrical, gas flow, and pumping symmetry for improved plasma uniformity control.

### Description of the Related Art

Semiconductor substrates are processed for a wide variety of applications, including the fabrication of integrated devices and micro devices. One such processing device is an etch processing chamber. During processing, the substrate is positioned on a substrate support within the etch processing chamber. Gas is introduced into the etch chamber and ignited into a plasma for etching a substrate. The symmetry of the plasma as gas across the substrate help to ensure process uniformity. Depending on the fabrication technique, the substrate support may be configured to operate at either a high temperature, such as temperatures exceeding 200 degrees Celsius or at cryogenic temperatures, such as temperatures below negative 100 degrees Celsius. The substrate support configured for operating at high temperatures or alternately at cryogenic temperatures have different mechanical and plumbing constraints within etch processing chambers resulting in unique constraints.

The symmetry of the pressure, electrical, gas flow, and temperature across the substrate can affect the uniformity of the material etched or deposited on the substrate. Precise control over pressure, electrical, gas flow, temperature and conductance through the chamber allow the substrate to be processed within very strict tolerances. The ability to precisely control the symmetry of the etch processing chamber has a significant impact on throughput and production yields. Conventional etch processing chambers have difficulty providing symmetrical process conditions desirable for fabricating next generation devices, while meeting ever increasing demands for improved production yields and faster throughput. As substrate supports become more crowded with electrical feeds and control wires, sensors, gas supply, cooling, and other utilities, it has become more difficult to use conventional supports for the substrate support while meeting symmetry requirements.

Therefore, a need exists for improved process symmetry in etch processing chambers.

### SUMMARY

Embodiments of the present disclosure provide an apparatus for processing a substrate. In one example, the apparatus is disclosed as a flow module. The flow module has an inner wall. The flow module has an outer wall equal-distant from the central axis. The flow module has radial walls connected between the outer wall and the inner wall, wherein the outer wall, inner wall and two or more pairs of radial walls define evacuation channels and a center portion. The center portion and evacuation channels are fluidly isolated from each other in the flow module. Two or more through holes are formed through the outer wall and fluidly coupled to the center portion. At least two of the two or more through holes are 180 degrees apart and linearly aligned through the central axis.

In another embodiment, a processing chamber is provided. A processing chamber has a process module enclosing a process region and an evacuation channel assembly. The evacuation channel assembly has a central axis and a flow module. The flow module has an inner wall. The flow module has an outer wall equal-distant from the central axis. The flow module has radial walls connected between the outer wall and the inner wall, wherein the outer wall, inner wall and two or more pairs of radial walls define evacuation channels and a center portion. The center portion and evacuation channels are fluidly isolated from each other in the flow module. Two or more through holes are formed through the outer wall and fluidly coupled to the center portion. At least two of the two or more through holes are 180 degrees apart and linearly aligned through the central axis. The evacuation channel assembly additionally has a substrate support chassis sealingly coupled to the inner wall of the flow module. A substrate support assembly has a support plate and a base. The support plate is disposed in the process region to support a substrate therein and the base extends from the process region of the process module to the center portion of the flow module, wherein the base is accessible through the two or more through holes.

In yet another embodiment, a processing platform is provided. The processing platform has a transfer chamber having a transfer chamber robot. The processing platform has a load lock chamber coupled to the transfer chamber and a factory interface. A plurality of processing chambers coupled to the transfer chamber at a slit valve door, wherein at least one of the processing chambers has a process module enclosing a process region and an evacuation channel assembly. The evacuation channel assembly having a central axis and a flow module. The flow module has an inner wall and an outer wall equal-distant from the central axis. The flow module has radial walls connected between the outer wall and the inner wall, wherein the outer wall, inner wall and two or more pairs of radial walls define evacuation channels and a center portion. The center portion and evacuation channels are fluidly isolated from each other in the flow module. Two or more through holes are formed through the outer wall and fluidly coupled to the center portion. At least two of the two or more through holes are 180 degrees apart and linearly aligned through the central axis. The evacuation channel assembly additionally has a substrate support chassis sealingly coupled to the inner wall of the flow module. A substrate support assembly has a support plate and a base. The support plate is disposed in the process region to support a substrate therein and the base extends from the process region of the process module to the center portion of the flow module, wherein the base is accessible through the two or more through holes.

### BRIEF DESCRIPTION OF THE DRAWINGS

So that the manner in which the above recited features of the present disclosure are attained and can be understood in detail, a more particular description of the disclosure, briefly summarized above, may be had by reference to the embodiments thereof which are illustrated in the appended drawings.

FIG. 1A is a schematic cross-sectional view of a processing chamber according to one or more embodiments of the disclosure.

FIG. 1B is a schematic cross-sectional view of a processing chamber according to one or more embodiments of the disclosure.

FIG. 1C is a schematic cross-sectional view of a processing chamber according to one or more embodiments of the disclosure.

FIG. 2A is schematic top isometric view for a first example of a flow block for a first example of the processing chamber of FIGS. 1A-1C.

FIG. 2B is bottom isometric view for a substrate support chassis suitable for use with a flow block of FIG. 2A.

FIG. 2C is a first schematic platform layout for the first example of the processing chamber of FIGS. 2A and 2B.

FIG. 2D is a second schematic platform layout for the first example of the processing chamber of FIGS. 2A and 2B.

FIG. 3A is schematic top plan view for a second example of a flow block for the processing chamber of FIGS. 1A-1C.

FIG. 3B is top plan view for a substrate support chassis suitable for use with the flow block of FIG. 3A.

FIG. 3C is a schematic layout for a processing platform having the processing chamber configured in accordance to FIGS. 3A and 3B.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this disclosure and are therefore not to be considered limiting of its scope, for the disclosure may admit to other equally effective embodiments.

### DETAILED DESCRIPTION

A processing chamber is provided for patterning features and manufacturing nanostructures with desired small dimensions in a film stack, substrate. The processing chamber includes a symmetrical pumping system. The symmetrical pumping system helps maintain symmetrical electrical, thermal, and gas flow conductance in the processing chamber.

In one example, the chamber is configured with two symmetric evacuation channels about central axis of a substrate support disposed inside the chamber. The two evacuation channels are 180 degrees apart and in-line with slit valve door. The conductance of the two evacuation channels increase the fluid removal area by about 18% compared to standard three pump ports. The bias match and feed connection for operating the substrate support is disposed on the front outer side opposite the slit valve door opening for facilitating connections to the substrate support.

In an alternate example, the chamber is configured with two symmetric evacuation channels as above but the bias match and feed connection are disposed on one outer side adjacent to slit valve door. The opposite side opening is available for additional connections to the substrate support. The arrangement for the bias match location provides a reduced footprint advantage over the prior example for the platform in which the chamber is attached.

In another example, the chamber is configured with four symmetric evacuation channels about central axis of a substrate support disposed inside the chamber. The four evacuation channels are 90 degrees apart and in-line with slit valve door. The conductance of the four evacuation channels decrease the fluid removal area compared to standard three pump ports. However, the fully symmetric flow chamber with four atmospheric openings to the substrate support provides additional room for advance designs and connections for RF, AC, DC, cooling hoses, He lines, optical fibers, cryogenic lines, additional sensors and other utilities. In particular, the fully symmetric flow chamber with four atmospheric openings enables the integration of a cryogenic substrate support, where processing temperatures are less than 0 degrees Celsius, having feature connections exceeding the available room in conventional three port designs.

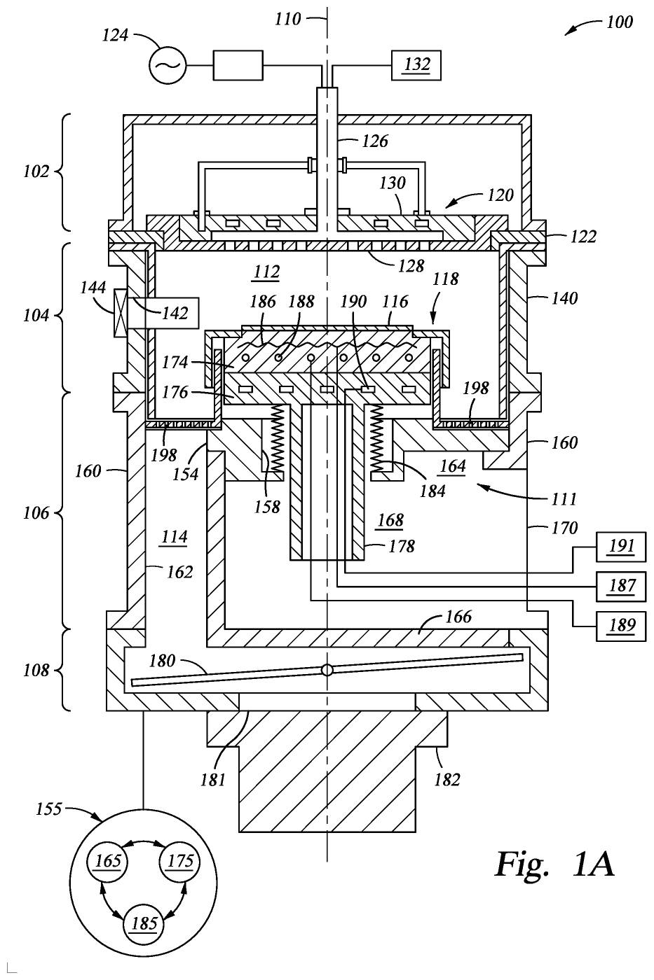

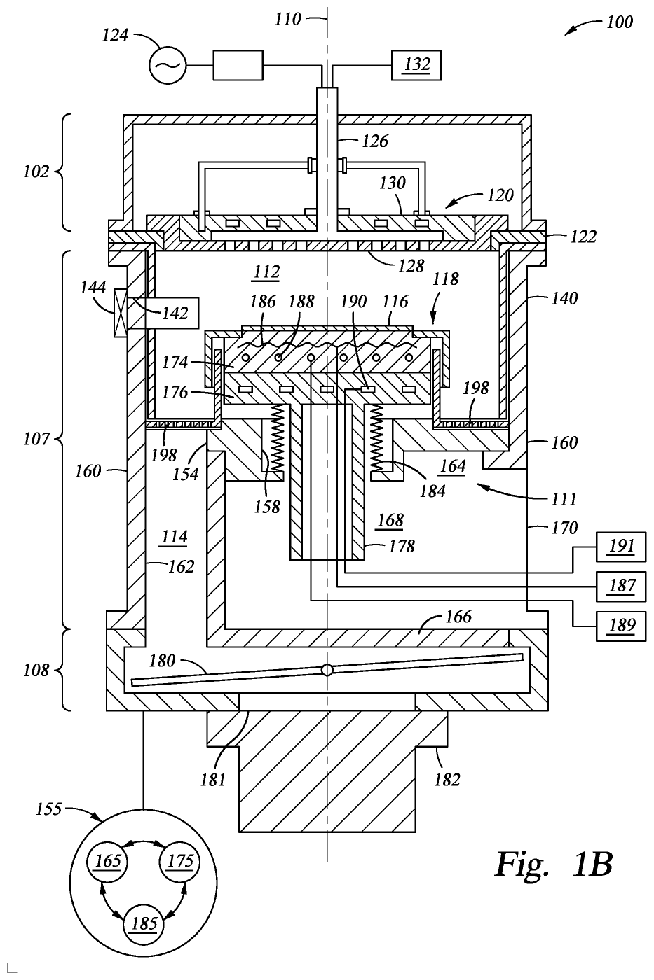

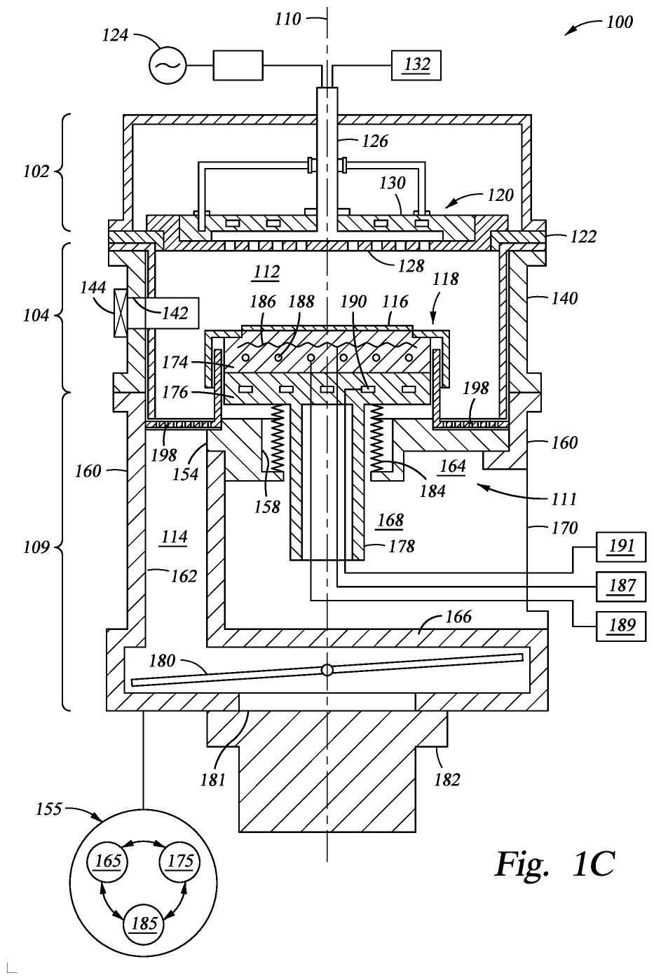

FIG. 1A is a schematic cross-sectional view of a processing chamber 100 according to one or more embodiments of the disclosure. The exemplary processing chamber 100 is suitable for patterning a material layer disposed on a substrate 116 in the processing chamber 100. The exemplary processing chamber 100 is suitable for performing a patterning process. The processing chamber 100 may be a plasma etch chamber, a plasma enhanced chemical vapor deposition chamber, a physical vapor deposition chamber, a plasma treatment chamber, an ion implantation chamber, or other suitable vacuum processing chamber.

The processing chamber 100 has a body 140. The body 140 generally has four external surfaces. The body 140 includes a source block 102, a process block 104, a flow block 106, and an exhaust block 108. It should be appreciated that the blocks may be one or more combination of blocks. For example, the exhaust block 108 is integral with and a part of the flow block 106 and made as a single unified body 109 (As shown in FIG. 1C). The flow block 106 is part of a pumping port assembly 111 that includes a substrate support chassis 154. The source block 102, the process block 104 and the flow block 106 collectively enclose a process region 112. During operation, a substrate 116 may be positioned on a substrate support assembly 118 and exposed to a process environment, such as plasma generated in the process region 112. Exemplary process which may be performed in the processing chamber 100 may include etching, chemical vapor deposition, physical vapor deposition, implantation, plasma annealing, plasma treating, abatement, or other plasma processes. Vacuum may be maintained in the process region 112 by suction from an exhaust port 181 formed in the exhaust block 108 through one or more evacuation channels, i.e., evacuation channels 114, defined in the flow block 106.

The process region 112 and the evacuation channels 114 are substantially symmetrically about a central axis 110 to provide symmetrical electrical current, gas flow, thermal and pressure uniformity to establish uniform process conditions.

The source block 102 includes an upper electrode 120 (or anode) isolated from and supported by the process block 104 by an isolator 122. The upper electrode 120 may include a showerhead plate 128 attached to a heat transfer plate 130. The upper electrode 120 may be connected to a gas source 132 through a gas inlet tube 126.

The gas source 132 may include one or more process gas sources and may additionally include inert gases, non-reactive gases, and reactive gases, if desired. Examples of process gases that may be provided by the gas source 132 include, but are not limited to, hydrocarbon containing gas including methane (CH₄), sulfur hexafluoride (SF₆), silicon chloride (SiCl₄), carbon tetrafluoride (CF₄), hydrogen bromide (HBr), hydrocarbon containing gas, argon gas (Ar), chlorine (Cl₂), nitrogen (N₂), helium (He) and oxygen gas (O₂). Additionally, process gasses may include nitrogen, chlorine, fluorine, oxygen and hydrogen containing gases such as BCl₃, C₂F₄, C₄F₈, C₄F₆, CHF₃, CH₂F₂, CH₃F, NF₃, NH₃, CO₂, SO₂, CO, N₂, NO₂, N₂O and H₂ among others.

The showerhead plate 128, the heat transfer plate 130, and the gas inlet tube 126 may be all fabricated from a radio frequency (RF) conductive material, such as aluminum or stainless steel. The upper electrode 120 may be coupled to a RF power source 124 via the conductive gas inlet tube 126. The conductive gas inlet tube 126 may be coaxial with the central axis 110 of the processing chamber 100 so that both RF power and processing gases from the gas source 132 are symmetrically provided.

The process block 104 is disposed on the flow block 106. An RF gasket for grounding and an O-ring seal is disposed between the process block 104 and the flow block 106. Alternately, the process block 104 and flow block 106 are combined and made as a single unified body 107 (As shown in FIG. 1B) with no RF gasket for grounding and O-ring seal between them.

The process block 104 encloses the process region 112. The process block 104 may be fabricated from a conductive material resistive to processing environments, such as aluminum or stainless steel. The substrate support assembly 118 may be centrally disposed within the process block 104 and positioned to support the substrate 116 in the process region 112 symmetrically about the central axis 110.

A slit valve opening 142 may be formed through the process block 104 to allow passages of the substrate 116. A slit valve 144 may be disposed outside the process block 104 to selectively open and close the slit valve opening 142.

The process block 104 is disposed on the flow block 106. The flow block 106 provides flow paths between the process region 112 defined in the process block 104 and the exhaust block 108. The flow block 106 also provides an interface between the substrate support assembly 118 and the atmospheric environment exterior to the processing chamber 100.

The flow block 106 has through-holes 170 and evacuation channels 114. The through-holes 170 are maintained at atmospheric pressure and provide access to the substrate support assembly 118. The evacuation channels 114 are maintained at vacuum and provides a fluid path for removing gasses from the process region 112 to outside the processing chamber 100.

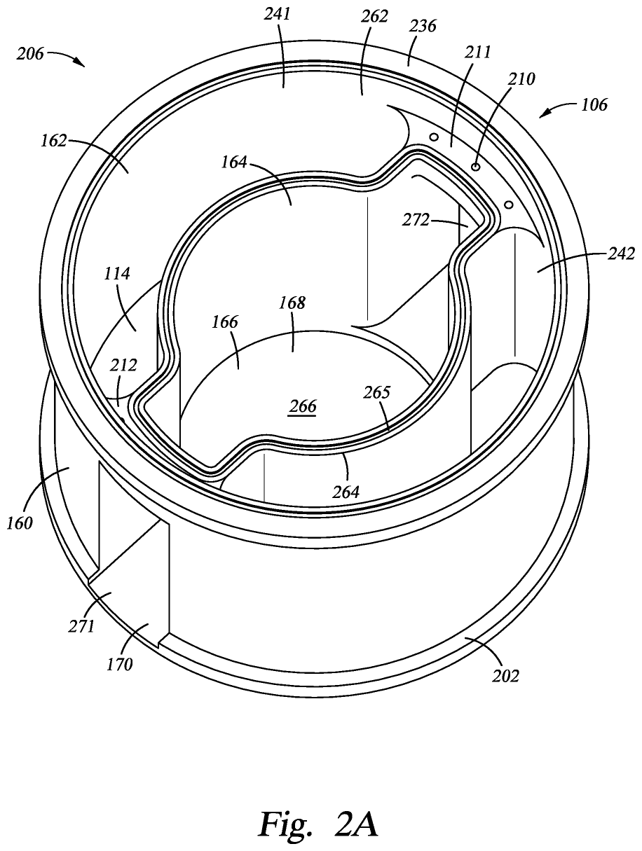

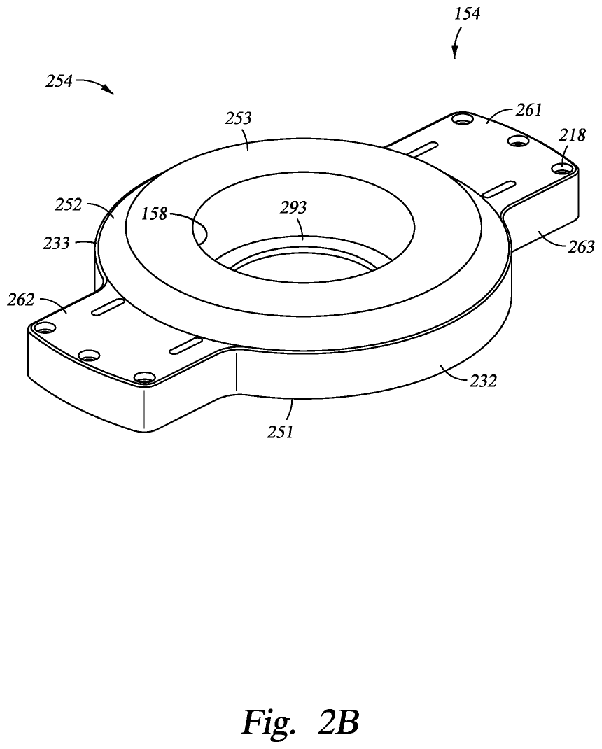

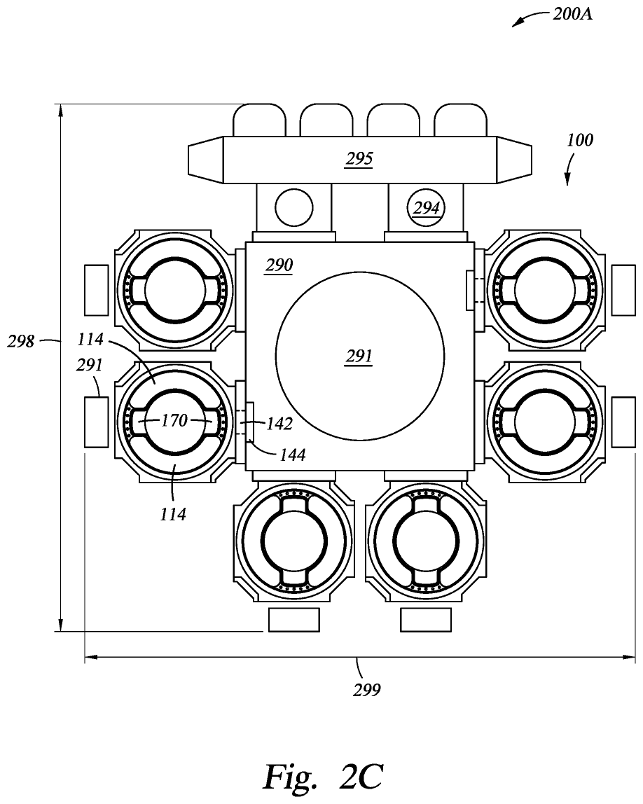

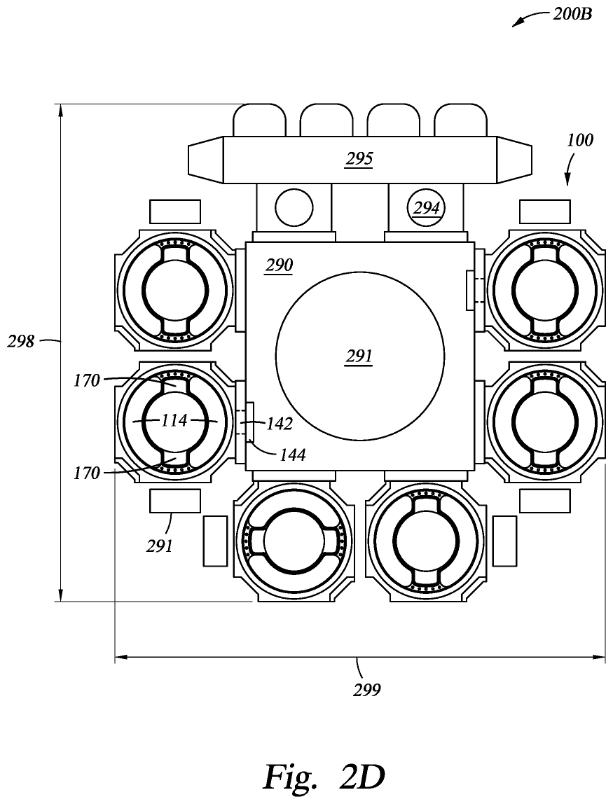

FIG. 2A provides additional illustration which may aid in understanding the following description of the flow block 106/206. The flow block 106 includes an outer wall 160, an inner wall 162, two or more pairs of radial walls 164 connecting between the inner wall 162 and the outer wall 160, and a bottom wall 166 attached to the inner wall 162 and the two or more pairs of radial walls 164. The outer wall 160 equal-distant from the central axis 110. The outer wall 160 may include two or more through-holes 170 formed between each pair of radial walls 164. The through-holes 170 connect an atmosphere volume 168 defined by the inner wall 162 with the exterior environment, thus accommodating utility connections, such as electrical connection, gas connection, cooling fluid connections, sensor leads and the like.

A chassis 154, shown in FIG. 2B and not here in FIG. 2A for purposes of clarity, may be sealingly disposed over the inner wall 162 and the two or more pairs of radial walls 164. The chassis 154 may include a central opening 158 for receiving the substrate support assembly 118. The chassis 154 and the central opening 158 are centered about central axis 110. The inner wall 162, bottom wall 166, radial walls 164 and the chassis 154 divide the volume inside the outer wall 160 into the evacuation channels 114 and the atmosphere volume 168. The evacuation channels 114 connect with the process region 112 of the process block 104. The two or more pairs of radial walls 164 are arranged between the inner wall 162 and the outer wall 160 to divide the space into the evacuation channels 114 and the through-holes 170. In one embodiment, the two or more pairs of radial walls 164 are arranged so that the evacuation channels 114 are symmetrical about the central axis 110.

The substrate support assembly 118 is supported by the chassis 154. The substrate support assembly 118 is positioned along the central axis 110 to position the substrate 116 symmetrically about the central axis 110. The substrate support assembly 118 includes a support plate 174, a base plate 176 that are disposed in the process region 112. The substrate support assembly 118 is disposed over the central opening 158 of the chassis 154. In one example, the substrate support assembly 118 is fixed to the chassis 154 and does not move. In another example, the substrate support assembly 118 has a hollow shaft 178. A bellows 184 may connect between the base plate 176 and the chassis 154 and surround the hollow shaft 178. The bellows 184 allows the substrate support assembly 118 to move vertically along the central axis 110 and provides vacuum seal between an atmospheric volume 168 in the flow block 106 and vacuum in the process region 112 in the process block 104.

The support plate 174 may be an electrostatic chuck having a chucking electrode 186. The support plate 174 may also include one or more heating elements 188 for heating the substrate 116 during processing. The base plate 176 may include cooling channels 190 formed therein. The chucking electrode 186 may be connected to a bias power source 187 through the base plate 176, the atmosphere volume 168 and one of the through-holes 170. The heating element 188 may be connected to a heating power source 189 through the base plate 176, the atmosphere volume 168 and one of the through-holes 170. The cooling channels 190 may be connected to a cooling fluid source 191 through the base plate 176, the atmosphere volume 168 and one of the through-holes 170.

During operation, one or more processing gases from the gas source 132 may enter the process region 112 through the showerhead plate 128. A RF power may be applied between the upper electrode 120 and the substrate support assembly 118 to ignite and maintain of the one or more processing gases in the process region 112. The substrate 116 disposed on the substrate support assembly 118 is processed by the plasma. The one or more processing gases may be continuously supplied to the process region 112 and the vacuum pump 182 operates through the symmetric flow valve 180 and the flow block 106 to generate a symmetric and uniform gas flow over the substrate 116.

The exhaust block 108 includes a symmetric flow valve 180 and a vacuum pump 182 attached to the symmetric flow valve 180. The symmetric flow valve 180 connects via the exhaust port formed in in the bottom of the exhaust block 108 to the evacuation channels 114 to provide symmetric and uniform flow in the processing chamber 100. In one example, the exhaust block 108 is part of the flow block 106.

A controller 155 may provide operational instructions to the processing chamber 100. The controller 155 may include support circuits 165, a central processing unit (CPU) 175 and memory 185. The CPU 175 may execute instructions stored in the memory 185 to control the process sequence, regulating the gas flows from the gas source 132 into the processing chamber 100 and other process parameters. Software routines may be stored in the memory 185. Software routines are executed by the CPU 175. The execution of the software routines by the CPU 175 controls the processing chamber 100 such that the processes are performed in accordance with the present disclosure. For example, the software routine may control the operation of the substrate support assembly 118 and the vacuum pump 182.

FIGS. 2A and 2B will be used to describe a first example of the pumping port assembly 111 having two symmetrical evacuation channels 114. FIG. 2A is schematic top isometric view for a first example of the flow block 106 for a first example of the processing chamber 100 of FIG. 1A. The flow block 206 is one particular example of the flow block 106 described above with respect to FIG. 1A. However, it should be appreciated that features of the flow block 106 are applicable to the version of the single unified body 107/109 shown in FIGS. 1B and 1C. The outer wall 160 of the flow block 206 may include a flange 236 at an upper end used to connect the flow block 206 with the process block 104. The outer wall 160 of the flow block 206 may include a second flange 202 at a lower end used to connect the flow block 206 with the exhaust block 108. However, it should be appreciated that in some examples, the flow block 206 may be integral to, or a part of, the exhaust block 108.

The flow block 206 has at least two areas, i.e., evacuation channels 114 and a center portion 266, which are configured to be fluidly isolated from each other such that one area can be maintained at a vacuum pressure while the other area can be maintained at an atmospheric pressure. The radial walls 164 extend from the inner wall 162 of the flow block 206 and fluidly separate the evacuation channels 114 from the center portion 266 of the flow block 106. The center portion 266 is bounded by the bottom wall 166 and the radial walls 164 to fluidly isolate and form an atmosphere volume 168 in the center portion 266 of the flow block 206.

The flow block 206 has two evacuation channels 114 that have a symmetrical shape and are equally sized. The flow block 206 extends along the inner wall 162 to about the through-hole 170 and back along the radial walls 164. In one example, the evacuation channels 114 in the flow block 206 form a first vacuum port 241 and a second vacuum port 242. The first vacuum port 241 and the second vacuum port 242 are symmetrical about the central axis 110 of the processing chamber 100. The processing chamber 100 conductance area for fluid flow through the first vacuum port 241 and the second vacuum port 242 may be between about 200 in² and about 220 in², such as about 212 in². The first vacuum port 241 and the second vacuum port 242 increase the conductance area by approximately 18% compared to a three vacuum port conventional design of approximately 180 in².

The through-hole 170 forms an opening which extends from the outer wall 160 to the inner wall 162. The through-holes 170 connect the atmosphere volume 168 defined by the inner wall 162 with the exterior environment, thus accommodating utility connections, such as electrical connection, gas connection, cooling fluid connection. Each through-hole 170 of the flow block 106 separates a respective evacuation channels 114. Thus, there are equal number of through-holes 170 and evacuation channels 114. The flow block 206 has two openings, a first opening 271 and a second opening 272 extending from the outer wall 160 to the inner wall 162. The first and second openings 271, 272 fluidly couples the center portion 266 with an environment outside the flow block 206. The first and second openings 271, 272 are linearly aligned through the central axis 110. The first and second openings 271, 272 are 180 degrees opposite each other on the inner wall 162 of the flow block 206. In this manner, the flow block 206 is symmetrical.

A top surface 264 extends across the top of the radial wall 164. The top surface 264 additionally extends across one or more opening top walls 212. The opening top walls 212 extending over the top of the first and second openings 271, 272. The top surface 264 forms a continuous flat ring shape. One or more alignment holes 210 may be formed on the top surface 264 along the opening top walls 212 for aligning with the chassis 154.

A gasket 265 may be disposed along the top surface 264. The gasket 265 forms a fluid seal between a chassis 154 (254 in FIG. 2B) and the top surface 264. In this manner, an atmosphere volume 168 is formed in the center portion 266 which is fluidly isolated from the vacuum pressure in the evacuation channels 114. The chassis 254 provides an interface between the flow block 206 and the substrate support assembly 118. FIG. 2B is bottom isometric view for the chassis 254 suitable for use with the flow block 106 of FIG. 2A. The chassis 254 is but one implementation of the chassis 154 shown in FIG. 1A.

The chassis 254 may include a disk shaped body 252 having wings 263 extending outward. The disk shaped body 252 has an outer perimeter 232, a bottom surface 253, and a top surface 251. The disk shaped body 252 has a lip 233. The lip 233 is sized to contact the gasket 265. The gasket 265 additionally contacts the wings 263. In one example, the lip 233 is planar with the wings 263. However it should be appreciated, that the lip 233 and their wings 263 do not have to be coplanar while making a seal with between the top surface 264 of the flow block 206 with the gasket 265.

The wings 263 extend from the outer perimeter 232 of the disk shaped body 252. The number of wings 263 correspond to the number of through-holes 170 in the flow block 206. In one embodiment, the chassis 254 has two wings 263 positioned 180 degrees apart. The chassis 254 has a first wing 261 corresponding to a first opening 271 and a second wing 262 corresponding to a second opening 272. The wings 263 have one or more features 218. The features 218 may align or fasten to the alignment holes 210 in the flow block 206. The features 218 may be pins, holes or through-holes that aid in the locating and securing of the chassis 254 to the flow block 206.

In one example, the base plate 176 of the substrate support assembly is sealing disposed on the chassis 254. The central opening 158 of the chassis 254 may have a sealing flange 293. In another example, the hollow shaft 178 of the substrate support assembly 118 extends through the central opening 158 of the chassis 254. Bellows 184 couples to the sealing flange 293. The bellows 184 is provided between the substrate support assembly 118 and the chassis 254 such that the central opening 158 does not allow fluids, such as a gas, to move through the central opening 158 from the bottom surface 253 to the top surface 251 of the chassis 254, the evacuation channels 114, or the interior volume 112 of the processing chamber 100.

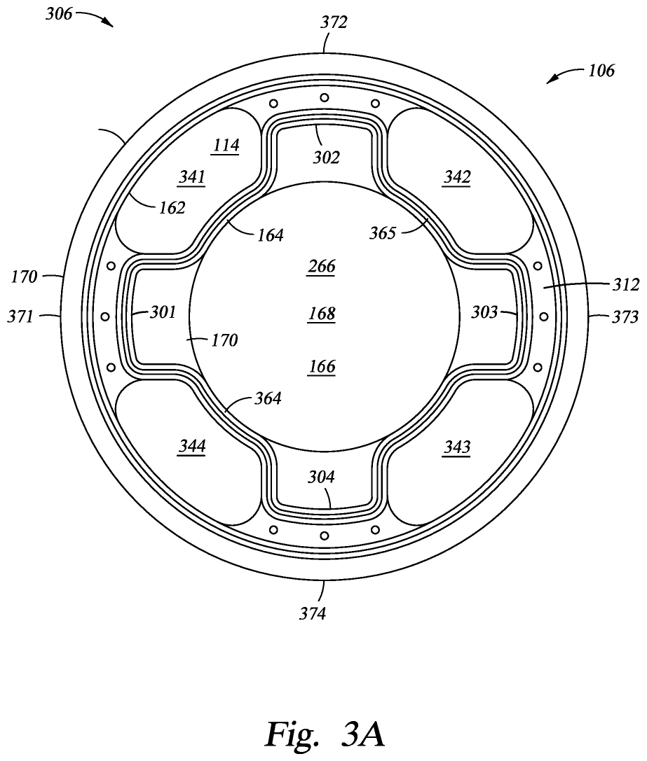

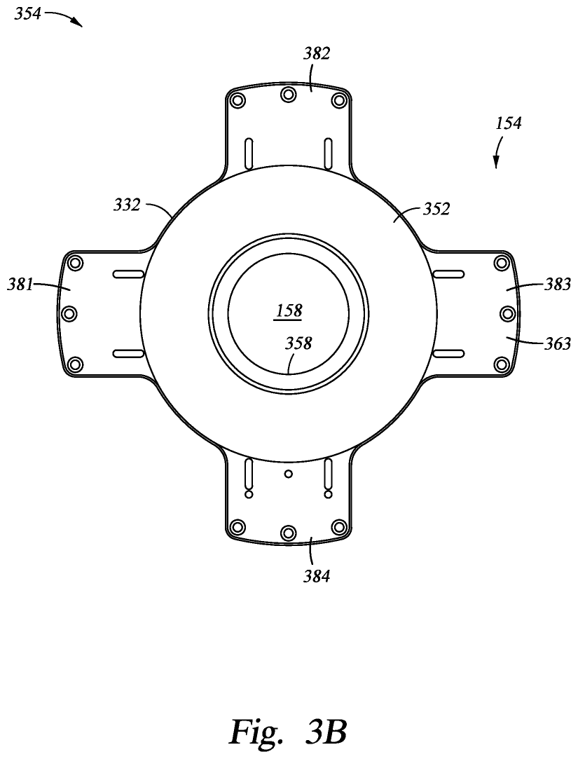

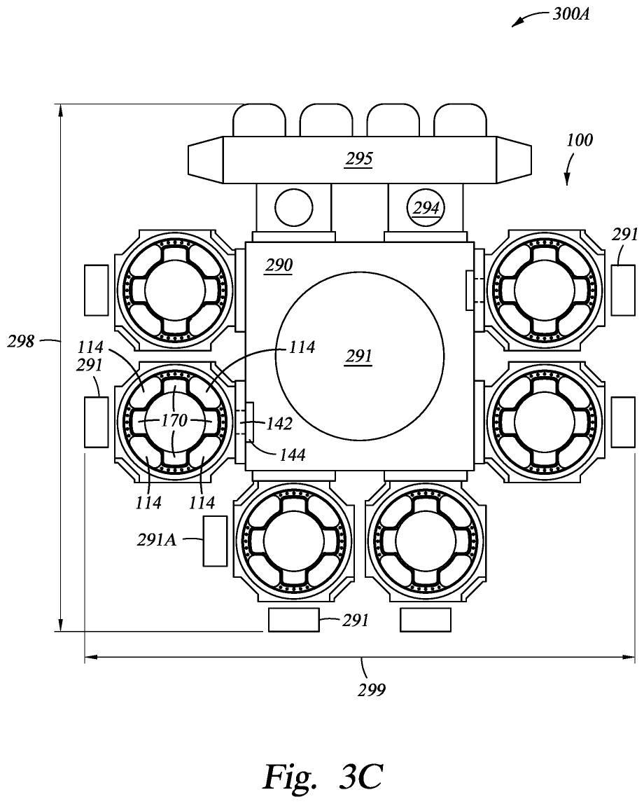

The substrate support assembly 118 has a plurality of connections extending through central opening 158 into the center portion 266 of the flow block 206 and out the first and second openings 271, 272. The connections electrical, gas, cooling fluid among other connections between the outside environment and the substrate support assembly 118. The larger the first and second openings 271, 272 are, the more connections can be accommodated through the openings. However, there is a limit to the size of the openings 170. Making one larger may introduce asymmetry in the chamber evacuation through the evacuation channels 114. Making both larger reduces the conductance through the evacuation channels 11, thus increasing back pressure and power consumption. The requirements for a large opening when one is needed is addressed with respect to the examples depicted in FIGS. 3A-3B below. Access to one or more of the openings facilitate the hookup of the processing chamber to a processing platform 200A.

FIG. 2C is a first schematic platform layout for the first example of a processing platform 200A having at least one the processing chambers 100 of FIGS. 2A and 2B. The processing platform 200A has a transfer chamber 290 with the transfer robot 291 disposed therein for moving substrates. The transfer chamber 290 is maintained at vacuum pressure and is coupled to one or more processing chambers, such as one or more processing chamber 100. The processing chamber 100 is also at vacuum pressure. The transfer chamber 290 is coupled by load lock chambers 294 to a factory interface 295. The factory interface 295 is maintained substantially at atmospheric pressure. The load lock chambers 294 allows the substrates to be moved from the vacuum environment in the transfer chamber 290 to the atmospheric pressure of the factory interface 295.

A slit valve door 144 may be disposed between each of the processing chambers 100 and the transfer chamber 290. When the slit valve door 144 is opened, the transfer robot 291 transfers the substrates through the slit valve opening 142 onto the substrate support assembly 118 in the processing chamber 100 for processing the substrate with a RF excited plasma. A bias match circuit 291 provides the electrical connections to the substrate support assembly 118 and RF power source (Not shown). The bias match circuit 291 prevents damage to the power source from the RF reflected from the plasma load. The bias match circuit 291 may be disposed on an external surface opposite of the external surface of the processing chamber 100 coupled to the transfer chamber 290.

The two openings 170 are 180 degrees part and aligned with the slit valve opening 142. The bias match circuit 291 and feed connection are on the opposite side to the slit valve door 144 for facilitating cathode connections to the substrate support assembly 118 through the through-holes 170. The location of the bias match circuit 291 on the processing chamber 100 allow for ease of access to the wiring and plumbing for the chamber.

FIG. 2D is a second schematic platform layout for the first example of the flow block 206 of FIGS. 2A and 2B. The processing platform 200B is similar to that of the processing platform 200A. However, the two evacuation channels 114 are aligned with the slit valve opening 142. This places the bias match circuit 291 and feed connection on one side of the processing chamber 100 relative to the transfer chamber with an opposite side open for cathode connections facilitation. That is, the bias match circuit 291 is disposed on an external surface of the processing chamber 100 adjacent to the external surface. This has the benefit of a reduced footprint (‘X’ 299×‘Y’ 298) for the processing platform 200B as compared to the processing platform 200A.

Symmetrical conductance for removing process gasses from within the processing chamber 100 improves process uniformity when processing substrates. Higher conductance reduces the amount of process material that may adhere to the chamber and introduce defects in later substrates undergoing processing in the chamber. However, the area afforded to the evacuation channels 114 in the flow block 206 comes at a cost for the area available for the through-holes 170 which the substrate support assembly 118 utilizes for both electrical and fluid/plumbing connections. In high temperature substrate support assemblies 118 the majority of the connections are electrical. However, cryogenic substrate support assemblies 118 have an increased number if fluid connections which increases the area required to route all the electrical and fluid/plumbing connections in the through-holes 170 for operating the substrate support assembly 118. It is not enough to increase the size of the opening for the connections as increase the size of the openings reduces the evacuation channel size while increasing the spacing between the evacuation channels. Thus, the increase the size of the opening results in asymmetry in the fluid flow removal from the chamber and may result in non-uniform processing for the substrates. In one example, the cryogenic operation of the substrate support assembly 118 have electrical and plumbing connections that exceed the area offered in conventional three evacuation channel flow blocks.

FIGS. 3A and 3B will be used to describe a second example of the pumping port assembly 111 having four symmetrical evacuation channels. FIG. 3A is schematic top plan view for a second example of a flow block 306 that can be used in the processing chamber of FIG. 1A. However, it should be appreciated that features of the flow block 306 are applicable to the version of the single unified body 107/109 shown in FIGS. 1B and 1C. The flow block 306 is substantially similar in many aspects to flow block 206 and another example of the flow block 106 described above with respect to FIG. 1A. The outer wall 160 of the flow block 106 may include the flange 236 to connect with the process block 104. The outer wall 160 of the flow block 106 may include the second flange 202 to connect with the exhaust block 108. However, it should be appreciated that in some examples, the flow block 306 may be integral to, or a part of, the exhaust block 108.

Similar to flow block 206, flow block 306 has at least two areas, i.e., evacuation channels 114 and a center portion 266, which are configured to be fluidly isolated from each other such that one area can be maintained at a vacuum pressure while the other area can be maintained at an atmospheric pressure. The radial walls 164 extend from the inner wall 162 of the flow block 306 and fluidly separate the evacuation channels 114 from the center portion 266 of the flow block 306. The center portion 266 is bounded by the bottom wall 166 and the radial walls 164 to fluidly isolate and form an atmosphere volume 168 in the center portion 266 of the flow block 306.

The flow block 306 has four evacuation channels 114 that have a symmetrical shape and are equally sized. The flow block 306 extends along the inner wall 162 to about the through-hole 170 and back along the radial walls 164. In one example, the evacuation channels 114 in the flow block 306 form a first vacuum port 341, a second vacuum port 342, a third vacuum port 343, and a fourth vacuum port 344. The first, second, third and fourth vacuum ports 341, 342, 343, 344 are symmetrical about the central axis 110 of the processing chamber 100. The processing chamber 100 conductance area for fluid flow through first, second, third and fourth vacuum ports 341, 342, 343, 344 is slightly reduced over conventional three port designs while maintaining symmetrical fluid flow around the substrate support assembly 118.

As discussed above with respect to flow block 206 and flow block 306, the through-hole forms an opening which extends from the outer wall 160 to the inner wall 162 in flow block 206 and 306. The through-holes 170 connect the atmosphere volume 168 defined by the inner wall 162 with the exterior environment, thus accommodating utility connections, such as electrical connection, gas connection, cooling fluid connection. Each through-hole 170 of the flow block 106 separates a respective evacuation channels 114. Thus, there are equal number of through-holes 170 and evacuation channels 114. The flow block 306 has four openings, a first opening 371, a second opening 372, a third opening 373, and a fourth opening 374 extending from the outer wall 160 to the inner wall 162. The first, second, third and fourth openings 371, 372, 373, 374 fluidly couple the center portion 266 with an environment outside the flow block 306. The first and third openings 371, 373 are linearly aligned through the central axis 110. Similarly, the second and fourth openings 372, 374 are linearly aligned through the central axis 110. The first opening 371 and the third opening 373 are each oriented about 90 degrees respectively from the second openings 372 and the fourth openings 374 on the inner wall 162 of the flow block 306. In this manner, the flow block 306 is symmetrical.

The area provided by the first, second, third and fourth openings 371, 372, 373 and 374 in the flow block 306 increase by about 33% the area provided for connections to the substrate support assembly 118 over conventional three through-hole designs for flow blocks while maintaining symmetrical fluid flow around the substrate support assembly 118 by the evacuation channels.

A top surface 364 extends across the top of the radial wall 164. The top surface 364 additionally extends across one or more opening top walls 312. The opening top walls 312 extend over the top of the first, second, third and fourth openings 371, 372, 373, 374. The top surface 364 forms a continuous flat ring shape. In one example, the flat ring shape has four lips extending from four radial aligned arc sections.

A gasket 365 may be disposed along the top surface 364. The gasket 365 forms a fluid seal between a chassis 354 (shown in FIG. 3B) and the top surface 364. In this manner, an atmosphere volume 168 is formed in the center portion 266 which is fluidly isolated from the vacuum pressure in the evacuation channels 114 in flow block 306 similar to that of flow block 206. The chassis 354 provides an interface between the flow block 306 and the substrate support assembly 118.

FIG. 3B is top plan view of the substrate support chassis 354 suitable for use with the flow block 306 of FIG. 3A. The chassis 354 is substantially similar in many aspects to chassis 254 and but another implementation of the chassis 154 shown in FIG. 1A.

The chassis 354 includes a disk shaped body 352 having wings 363 extending outward. The disk shaped body 352 has an outer perimeter 332, a bottom surface 353, and a top surface 351. The outer perimeter 332 is generally circular in shape and interrupted at each of the wings 363. The disk shaped body 352 is sized to contact the gasket 365. The gasket 365 additionally contacts the wings 363. In one example, the gasket 365 is coplanar in its contact with the disk shaped body 352 and the wings 363. However, it should be appreciated, that the gasket may not be planar while forming the seal between the top surface 364 of the flow block 306 and the chassis 354.

The wings 363 extend from the outer perimeter 332 of the disk shaped body 352. The number of wings 363 correspond to the number of through-holes 170 in the flow block 306. In one example, the chassis 354 has four wings 363 positioned at 90 degrees apart. The chassis 354 has a first wing 381 corresponding to a first opening 371, a second wing 382 corresponding to a second opening 372, a third wing 383 corresponding to a third opening 373, and a fourth wing 384 corresponding to a fourth opening 374. The wings 363 have one or more features similar to those described with respect to chassis 254 wherein the features 218 align or fasten to the alignment holes in the flow block 306.

The substrate support assembly 118 has a plurality of connections extending through the central opening 158 into the center portion 266 of the flow block 306 and out the first, second, third and fourth openings 371, 372, 373, 374. The connections electrical, gas, cooling fluid among other connections between the outside environment and the substrate support assembly 118. The greater number of openings, i.e., the first, second, third and fourth openings 371, 372, 373, 374, accommodate more connections the substrate support assembly 118. In one example, the substrate support assembly 118 is configured for cryogenic processing and has a greater number of fluid connections than a high temperature substrate support assembly. Access to the four openings facilitate the hookup of the substrate support assembly 118 in the processing chamber 100 as well as the processing chamber 100 to a processing platform 300A.

The conductance area for the flow block 306 will decrease slightly compared to conventional three port pump ports designs. However, the flow block 306 advantageously offers fully symmetric flow with four atmospheric through-holes 170 providing additional room for cathode facilitation, i.e., future cathode advance designs with RF, AC, DC, cooling hoses, helium lines, optical fibers, cryogenic lines, additional sensors and other potential features which cannot be accommodated in current conventional designed flow blocks.

FIG. 3C is a schematic layout for a processing platform 300A having the processing chamber 100 configured in accordance to FIGS. 3A and 3B. The processing platform 300A is substantially similar to processing platform 200A having the transfer chamber 290 with the transfer robot 291. The transfer chamber 290 is at vacuum pressure and coupled to one or more processing chambers, such as processing chamber 100. The processing chamber 100 being at vacuum pressure. The transfer chamber 290 is coupled by load lock chambers 294 to the factory interface 295. The factory interface 295 is at atmospheric pressure.

The slit valve door 144 is disposed between transfer chamber 290 and the processing chamber 100. The transfer robot 291 moves the substrates through the slit valve door 144 onto the substrate support assembly 118 in the processing chamber 100 for processing the substrate with a RF excited plasma. The bias match circuit 291 provides the electrical connections to the substrate support assembly 118 while preventing damage to components outside the chamber from coupled RF.

The through-holes 170 are 90 degrees part with one through-holes 170 in-line with the slit valve door 144. The bias match circuit 291 and feed connection are on the opposite side to the slit valve door 144 for facilitating cathode connections to the substrate support assembly 118 through the through-holes 170. The configuration of the bias match 291 on the processing chamber 100 allow for ease of access to the wiring for the chamber. The cryogenic substrate support assembly 118 has the through-holes 170 adjacent to the bias match circuit 291 available to use for the additional plumbing of the cryogenic substrate support assembly 118.

Alternately, the bias match circuit 291 is provided on one side of the processing chamber 100 adjacent the slit valve door 144. The adjacent side opposite the slit valve door and the opposite side to the bias match circuit 291 are open for cathode connections facilitation. This has the benefit of a reduced footprint (‘X’ 299×‘Y’ 298) for the processing platform 300A. In yet another alternative, flow block 306 in the processing chamber 100 is at 45 degrees to that shown in FIG. 3C. The evacuation channels 114 align with the slit valve door 144. In this arrangement, access is provided to all four of the through-holes 170 and the bias match 291 can be arranged to facilitate enhanced access to the through-holes 170 while additionally reducing the footprint of the processing platform 300A.

Advantageously, the flow blocks disclosed above provide symmetrical chamber electrical, thermal, and gas flow conductance. The flow blocks provide access to process region for by-product removal with symmetric evacuation channels about central axis of substrate support while allowing for additional room for cryogenic and other advancements in substrate support assemblies requiring additional connections for RF, AC, DC, cooling hoses, helium or other gas lines, optical fibers, cryogenic lines, sensors and other potential features.

While the foregoing is directed to embodiments of the present disclosure, other and further embodiments of the disclosure may be devised without departing from the basic scope thereof, and the scope thereof is determined by the claims that follow.

We claim:

1. A processing chamber for processing a substrate, comprising:
a process module enclosing a process region;
a central axis vertically disposed through a center of the processing chamber;
a flow module comprising:
a plurality of outer walls equal-distant from a central axis;
an inner wall;
four pairs of radial walls connecting the outer walls and the inner wall, wherein the outer walls, the inner wall and the four pairs more pairs of radial walls define four evacuation channels and a center portion, the center portion and evacuation channels fluidly isolated from each other by the inner and radial walls; and
first, second, third and fourth through holes formed through the outer wall and fluidly coupled to the center portion, wherein the first, second, third and fourth through holes are 90 degrees apart and radially aligned through the central axis;
a substrate support chassis, the chassis being sealingly coupled to the inner wall of the flow module; and
a substrate support assembly comprising a support plate and an interior region below the support plate, wherein the support plate is disposed in the process region to support a substrate therein, wherein the interior region is accessible through the four through holes.

2. The processing chamber of claim 1, wherein the evacuation channels are symmetrical.

3. The processing chamber of claim 1 further comprising:
an exhaust port disposed centrally below the substrate support assembly.

4. The processing chamber of claim 1 further comprising:
slit valve door formed through an external surface of the processing chamber, the slit valve door aligned with and disposed above one of the four through holes.

5. A processing platform comprising:
a transfer chamber having a transfer chamber robot;
a load lock chamber coupled to the transfer chamber and a factory interface; and
a plurality of processing chambers shaped with four external surfaces and coupled to the transfer chamber at a slit valve door on a first external surface of the four external surfaces, wherein at least one of the processing chambers comprises the processing chamber of claim 1.

6. The processing platform of claim 5, wherein the evacuation channels are symmetrical.

7. The processing platform of claim 5 further comprising:
an exhaust port disposed centrally below the substrate support assembly.

8. The processing platform of claim 5 further comprising:
slit valve door formed through an external surface of the processing chamber, the slit valve door aligned with and disposed above one of the four through holes.

9. The processing platform of claim 5 further comprising:
a match circuit is electrically coupled to the substrate support assembly and the match circuit is attached to one of the four external surfaces of the processing chamber and wherein the match circuit is attached at one of the four through holes.

10. The processing platform of claim 9, wherein the match circuit is on a second external surface opposite the first external surface having the slit valve.

11. The processing platform of claim 9, wherein the match circuit is on a third external surface adjacent the first external surface having the slit valve.
